(19) United States
(12) Patent Application Publication
(10) Pub. No.: US 2013/0082026 A1
(43) Pub. Date: Apr. 4, 2013

(54) Method for chemically plating metal on surface of capacitive touch panel

(71) Applicants: Qingyuan Cai, Wuxi (CN); Masahide Nishi, Wuxi (CN)

(72) Inventors: Qingyuan Cai, Wuxi (CN); Masahide Nishi, Wuxi (CN)

(21) Appl. No.: 13/701,496

(22) PCT Filed: May 28, 2011
(86) PCT No.: PCT/CN2011/074833

§ 371 Date: Nov. 30, 2012

(30) Foreign Application Priority Data
Jun. 1, 2010 (CN) 201010188452.9

(51) Int. Cl. H03K 17/96

(52) U.S. Cl. CPC H03K 17/962
USPC 216/13

(57) ABSTRACT

A method for chemically plating metal on surfaces of a capacitive touch panel includes sputtering ITO on surfaces of a glass substrate of a capacitive touch panel to form a double-sided ITO glass; dividing the double-sided ITO glass into a visible region and a peripheral region of a touch glass according to layout; etching on the visible region of each touch glass via a photo art to form induction electrodes of a sensor and etching on the peripheral region thereof to form wiring traces; and thereafter printing a protecting film on the visible region of each touch glass and plating the wiring traces of each touch glass with metal via a chemical nickel plating art and a chemical gold plating art.

### CROSS REFERENCE OF RELATED APPLICATION

This is a U.S. National Stage under 35 U.S.C. 371 of the International Application PCT/CN2011/074833, filed May 28, 2011, which claims priority under 35 U.S.C. 119(a-d) to CN 201010188452.9, filed Jun. 1, 2010.

### BACKGROUND OF THE PRESENT INVENTION

1. Field of Invention

The present invention relates to a technological field of plating metal on a surface of a capacitive touch panel, and more particularly to a method for chemically plating metal on a surface of a capacitive touch panel.

2. Description of Related Arts

In order to satisfy a restriction of the chip on the loop input resistance, the resistance of a peripheral part of wiring traces of a capacitive touch panel is required to be reduced, and by chemically plating metal on the peripheral wiring traces, a well conductive metal film can be formed thereon.

The conventional capacitive touch panel is chemically plated with metal and usually includes a plurality of tiny plates of touch glass on a large plate of indium-tin-oxide (ITO) glass. Thus a conducting zone needs to be reserved at a periphery of the large plate of ITO glass for forming electrodes during plating; meanwhile the single tiny plate of touch glass is also required to form into a loop with the conducting zone alone, which necessitates enough space among each single tiny plate of touch glass for a routine of the loop; thereby the metal film can be formed on the ITO glass by electrically plating. An existence of the conducting zone reduces an actual usage efficiency of the large plate of ITO glass; meanwhile a metal layer is formed on the conducting zone, which increases a usage amount of metal plating bath to raise cost.

### SUMMARY OF THE PRESENT INVENTION

An object of the present invention is to provide a method for chemically plating metal on a surface of a capacitive touch panel, so as to improve an actual usage efficiency of ITO glass, save metal plating bath and reduce cost.

Accordingly, in order to accomplish the above objects, the present invention adopts following technical solutions.

By sputtering ITO on surfaces of a glass substrate of a capacitive touch panel, a double-sided ITO glass is obtained. Then a visible region and a peripheral region are divided out of the touch glass of the double-sided ITO glass according to layout, wherein induction electrodes of a sensor are formed via etching in the visible region of each touch glass and wiring traces are formed via etching in the peripheral region via a photo art. Thereafter, a plating protecting film is printed on the visible region of each touch glass and then, via arts of chemical nickel plating and chemical gold plating, the wiring traces of each touch glass is plated with metal, wherein the plating protecting film is resistant to strong acids and high temperature and free of attachment of metal particles of Ni and Au.

The present invention includes following specific steps of:

(1) sputtering ITO on double sides of a glass substrate of a capacitive touch panel to obtain a double-sided ITO glass and dividing a visible region and a peripheral region out of each touch glass of the double-sided ITO glass according to layout;

(2) etching on the visible region of each touch glass via a photo art to form induction electrodes at directions of X and Y of a sensor and etching on the peripheral region to form wiring traces at the directions of X and Y of the sensor;

(3) printing a plating protecting film on the visible region of each touch glass, wherein the plating protecting film can be silk-screen printed on the induction electrodes on the visible region by printing ink which is resistant to strong acids and high temperature and free of attachment of Ni and Au particles; and

(4) pre-treating the double-sided ITO glass and thereafter processing the wiring traces on the peripheral region of each touch glass firstly with a chemical nickel plating art and then with a chemical gold plating art to strengthen wiring.

Further, the plating protecting film includes 55% to 65% vinyl acetate resin derivative, 10% to 20% fatty acid ester, 10% to 20% epoxy ester, polymeric fire retardant less than 5%, thixotropic agent less than 5%, organic pigment less than 1% and defoaming agent less than 3% in weight.

Further, the photo art includes steps of etching on each touch glass arranged on the double-sided ITO glass to form the induction electrodes and the wiring traces of the sensor at the directions of X and Y via the photo art by using photoresist and protecting films.

Further, the step of pre-treating the double-sided ITO glass includes following steps of:

(1) degreasing, including:

processing the double-sided ITO glass with a dip treatment in a standard acid bath at 15-28° C. for 5 minutes and thereafter washing with water for 2 minutes;

(2) etching, including:

processing the double-sided ITO glass with a dip treatment in an etching solution containing 10-50 g/L or 10-50 mL/L acidic etchant at 10-50° C. for 1-10 minutes and thereafter washing with water for 2 minutes;

(3) sensitizing, including:

processing the double-sided ITO glass with a dip treatment in a solution containing 10-50 mL/L palladium chloride and 15 mL/L KOH solution which contains KOH 0.1 mol/L at 10-50° C. for 1-10 minutes and thereafter washing with water for 2 minutes; and

(4) activating, including:

processing the double-sided ITO glass with a dip treatment in a solution containing 10 mL/L activator at 10-50° C. for 1-10 minutes and thereafter washing with water for 2 minutes.

Further, in a situation of plating metal on a substrate having delicately arranged wirings, the chemical nickel plating art and the chemical gold plating art include steps of: providing the double-sided ITO glass in a sodium-free plating bath having lead as a metal stabilizer, a pH of 1-5, a temperature of 50-100° C. and a film stress of ±0 for chemically plating nickel thereon, then washing the double-sided ITO glass chemically plated with nickel with water for 2 minutes and thereafter providing the washed double-sided ITO glass in a cyanide plating bath having a pH of 1-5 and a temperature of 50-100° C. for chemically plating gold thereon.

Further, in a situation of plating metal to thicken over 1 μm, the chemical nickel plating art and the chemical gold plating art include steps of: providing the double-sided ITO glass in a plating bath which has lead as a metal stabilizer, a pH of 1-5, a temperature of 50-100° C. and a low film stress and is suitable for trials and thickening the plating films, so as to chemically plate nickel thereon, then washing the double-sided ITO glass chemically plated with nickel with water for 2 minutes and thereafter providing the washed double-sided ITO glass in a lowly erosive plating bath having a pH of 6-10 and a temperature of 50-100° C. for chemically plating gold thereon.

Further, in a situation of satisfying Restriction of Hazardous Substances (RoHS), the chemical nickel plating art and the chemical gold plating art include steps of: providing the double-sided ITO glass in a plating bath which has none metal stabilizer, a pH of 6-10, a temperature of 50-100° C. and a low film stress and is suitable for trials to chemically plate gold thereon, wherein sulfur-based additive is added to maintain stability of the plating bath, washing the double-sided ITO glass chemically plated with nickel with water for 2 minutes and thereafter providing the washed double-sided ITO glass in a basically non-cyanide plating bath having a pH of 6-10 and a temperature of 50-100° C. for chemically plating gold thereon.

Beneficial Effects

By adopting the method of the present invention, the visible region of each touch glass is etched via the photo art to form the induction electrodes of the senor and the peripheral region thereof is etched to form the wiring traces; then the visible region of each touch glass is printed with the plating protecting film and the wiring traces of each touch glass is plated with metal via the chemical nickel plating art and the chemical gold plating art, wherein the plating protecting film is resistant to strong acids and high temperature and free of the attachment of the metal particles of Ni and Au. As a result, a conducting zone is completely eliminated and the actual usage efficiency of the ITO glass is greatly improved; meanwhile without the conducting zone, a usage amount of the metal plating bath is reduced, so as to save cost.

These and other objectives, features, and advantages of the present invention will become apparent from the following detailed description, the accompanying drawings, and the appended claims.

### DETAILED DESCRIPTION OF THE PREFERRED EMBODIMENT

### Embodiment One

The method for plating metal on a substrate having delicately arranged wirings includes following steps of:

(1) sputtering ITO on surfaces of a glass substrate of a capacitive touch panel to form a double-sided ITO glass, forming a touch glass by the integral double-sided ITO glass and dividing the touch glass into two parts, i.e., a visible region and a peripheral region;

(2) respectively etching on the double-sided visible region via a photo art to form induction electrodes of a sensor at directions of X and Y and etching on the peripheral region at an accordant side to respectively form wiring traces of the sensor at the directions of X and Y;

(3) printing a plating protecting film on the visible region, wherein the plating protecting film can be silk-screen printed on the induction electrodes on the visible region by printing ink which is resistant to strong acids and high temperature and free of attachment of Ni and Au particles; and the plating protecting film includes 55% vinyl acetate resin derivative, 10% fatty acid ester, 10% epoxy ester, polymeric fire retardant less than 5%, thixotropic agent less than 5%, organic pigment less than 1% and defoaming agent less than 3% in weight; and

(4) pre-treating the double-sided ITO glass and thereafter processing the wiring traces on the peripheral region firstly with a chemical nickel plating art and then with a chemical gold plating art to strengthen wiring.

The step (4) further includes following steps of:

(a) degreasing, including:

processing the double-sided ITO glass with a dip treatment in a standard acid bath at 15° C. for 5 minutes and then washing with water for 2 minutes;

(b) etching, including:

processing the double-sided ITO glass with a dip treatment in an etching solution containing 10 g/L acidic etchant at 10° C. for 5 minutes and thereafter washing with water for 2 minutes to slightly roughen the ITO surfaces and improve adhesion of the plates;

(c) sensitizing, including:

processing the double-sided ITO glass with a dip treatment in a solution containing 10 mL/L palladium chloride and 15 mL/L KOH solution which contains KOH 0.1 mol/L at 10° C. for 1 minute and thereafter washing with water for 2 minutes;

(d) activating, including:

processing the double-sided ITO glass with a dip treatment in a solution containing 10 mL/L activator at 10° C. for 1 minute and thereafter washing with water for 2 minutes;

(e) chemically plating nickel, including:

providing the double-sided ITO glass in a sodium-free plating bath having lead as a metal stabilizer, a pH of 1, a temperature of 50° C. and a film stress of ±0 for chemically plating nickel thereon and then washing the double-sided ITO glass chemically plated with nickel with water for 2 minutes; and

(f) chemically plating gold, including:

providing the washed double-sided ITO glass in a cyanide plating bath having a pH of 1 and a temperature of 50° C. for chemically plating gold thereon.

### Embodiment Two

The method for plating metal to thicken over 1 μm includes following steps of:

(1) sputtering ITO on surfaces of a glass substrate of a capacitive touch panel to form a double-sided ITO glass, forming six tiny touch glasses by the integral double-sided ITO glass and dividing each tiny touch glass into two parts, a visible region and a peripheral region;

(2) respectively etching on the double-sided visible region of each tiny ITO glass via a photo art to form induction electrodes of a sensor at directions of X and Y and etching on the accordant peripheral region thereof to respectively form wiring traces of the sensor at the directions of X and Y;

(3) printing a plating protecting film on the double-sided visible region of each tiny ITO glass, wherein the plating protecting film can be silk-screen printed on the induction electrodes on the visible region by printing ink which is resistant to strong acids and high temperature and free of attachment of Ni and Au particles; and the plating protecting film includes 60% vinyl acetate resin derivative, 15% fatty acid ester, 15% epoxy ester, polymeric fire retardant less than 5%, thixotropic agent less than 5%, organic pigment less than 1% and defoaming agent less than 3% in weight; and

(4) pre-treating the capacitive touch panel and thereafter processing the wiring traces on the peripheral region of each tiny ITO glass firstly with a chemical nickel plating art and then with a chemical gold plating art to strengthen wiring.

The step (4) further includes following steps of:

(a) degreasing, including:

processing the double-sided ITO glass with a dip treatment in a standard acid bath at 23° C. for 5 minutes and then washing with water for 2 minutes;

(b) etching, including:

processing the double-sided ITO glass with a dip treatment in an etching solution containing 25 g/L acidic etchant at 30° C. for 5 minutes and thereafter washing with water for 2 minutes to slightly roughen the ITO surfaces and improve adhesion of the plates;

(c) sensitizing, including:

processing the double-sided ITO glass with a dip treatment in a solution containing 30 mL/L palladium chloride and 15 mL/L KOH solution which contains KOH 0.1 mol/L at 30° C. for 5 minutes and thereafter washing with water for 2 minutes;

(d) activating, including:

processing the double-sided ITO glass with a dip treatment in a solution containing 10mL/L activator at 30° C. for 5 minutes and thereafter washing with water for 2 minutes;

(e) chemically plating nickel, including:

providing the double-sided ITO glass in a sodium-free plating bath which has lead as a metal stabilizer, a pH of 3, a temperature of 75° C. and a low film stress and is suitable for trails and thickening the plated films to chemically plate nickel thereon and then washing with water for 2 minutes; and

(f) chemically plating gold, including:

providing the washed double-sided ITO glass in a lowly erosive plating bath having a pH of 8 and a temperature of 75° C. for chemically plating gold thereon.

### Embodiment Three

The method of the present invention which satisfies RoHS includes following steps of:

(1) sputtering ITO on surfaces of a glass substrate of a capacitive touch panel to form a double-sided ITO glass, forming ten tiny touch glasses by the integral double-sided ITO glass and dividing each tiny touch glass into two parts, a visible region and a peripheral region;

(2) respectively etching on the double-sided visible region of each tiny ITO glass via a photo art to form induction electrodes of a sensor at directions of X and Y and etching on the accordant peripheral region thereof to respectively form wiring traces of the sensor at the directions of X and Y;

(3) printing a plating protecting film on the double-sided visible region of each tiny ITO glass, wherein the plating protecting film can be silk-screen printed on the induction electrodes on the visible region by printing ink which is resistant to strong acids and high temperature and free of attachment of Ni and Au particles; and the plating protecting film includes 65% vinyl acetate resin derivative, 20% fatty acid ester, 20% epoxy ester, polymeric fire retardant less than 5%, thixotropic agent less than 5%, organic pigment less than 1% and defoaming agent less than 3% in weight; and

(4) pre-treating the double-sided ITO glass and thereafter processing the wiring traces on the peripheral region of each tiny ITO glass firstly with a chemical nickel plating art and then with a chemical gold plating art to strengthen wiring.

The step (4) further includes following steps of:

(a) degreasing, including:

processing the double-sided ITO glass with a dip treatment in a standard acid bath at 28° C. for 5 minutes and then washing with water for 2 minutes;

(b) etching, including:

processing the double-sided ITO glass with a dip treatment in an etching solution containing 50 g/L acidic etchant at 50° C. for 5 minutes and thereafter washing with water for 2 minutes to slightly roughen the ITO surfaces and improve adhesion of the plates;

(c) sensitizing, including:

processing the double-sided ITO glass with a dip treatment in a solution containing 50 mL/L palladium chloride and 15 mL/L KOH solution which contains KOH 0.1 mol/L at 50° C. for 10 minutes and thereafter washing with water for 2 minutes;

(d) activating, including:

processing the double-sided ITO glass with a dip treatment in a solution containing 10mL/L activator at 50° C. for 10 minutes and thereafter washing with water for 2 minutes;

(e) chemically plating nickel, including:

providing the double-sided ITO glass in a sodium-free plating bath which has lead as a metal stabilizer, a pH of 10, a temperature of 100° C. and a low film stress and is suitable for trails to chemically plate nickel thereon, wherein sulfur-based additive is added to maintain stability of the plating bath, and then washing with water for 2 minutes; and

(f) chemically plating gold, including:

providing the washed double-sided ITO glass in basically non-cyanide plating bath having a pH of 10 and a temperature of 100° C. for chemically plating gold thereon.

RoHS is a mandatory standard made by European Union, whose full name is Restriction of Hazardous Substances.

One skilled in the art will understand that the embodiment of the present invention as shown in the drawings and described above is exemplary only and not intended to be limiting.

It will thus be seen that the objects of the present invention have been fully and effectively accomplished. Its embodiments have been shown and described for the purposes of illustrating the functional and structural principles of the present invention and is subject to change without departure from such principles. Therefore, this invention includes all modifications encompassed within the spirit and scope of the following claims.

What is claimed is:

1. A method for chemically plating metal on a surface of a capacitive touch panel, comprising:
sputtering ITO on surfaces of a glass substrate of a capacitive touch panel to form a double-sided ITO glass and dividing the double-sided ITO glass which is a touch glass into a visible region and a peripheral region according to layout;
then etching on the visible region of each touch glass via a photo art to form induction electrodes of a sensor and etching on the peripheral region thereof to form wiring traces;
and thereafter printing a plating protecting film on the visible region of each touch glass and plating metal on the wiring traces of each touch glass via a chemical nickel plating art and a chemical gold plating art, wherein the plating protecting film is resistant to strong acids and high temperature and free of attachment of metal particles of Ni and Au.

2. The method, as recited in claim 1, specifically comprising following steps of:
(1) sputtering the ITO at two sides of the glass substrate of the capacitive touch panel to form the double-sided ITO glass and dividing the double-sided ITO glass to form the visible region and the peripheral region of the touch glass according to the layout;
(2) etching on the visible region of each touch glass via the photo art to form the induction electrodes of the sensor at directions of X and Y and etching on the peripheral region thereof to form the wiring traces of the sensor at the directions of X and Y;
(3) printing the plating protecting film on the visible region of each touch glass, wherein the plating protecting film can be silk-screen printed on the induction electrodes of the visible region by printing ink which is resistant to strong acids and high temperature and free of attachment of the metal particles of Ni and Au; and
(4) pre-treating the double-sided ITO glass and then processing the wiring traces on the peripheral region of each touch glass firstly with a chemical nickel plating art and then a chemical gold plating art to strengthen wiring.

3. The method, as recited in claim 1, wherein the plating protecting film comprises 55% to 65% vinyl acetate resin derivative, 10% to 20% fatty acid ester, 10% to 20% epoxy ester, polymeric fire retardant less than 5%, thixotropic agent less than 5%, organic pigment less than 1% and defoaming agent less than 3% in weight.

4. The method, as recited in claim 2, wherein the photo art specifically comprises etching on each touch glass arranged on the double-sided ITO glass to form the induction electrodes and the wiring traces of the sensor at the directions of X and Y by using photoresist and protecting films.

5. The method, as recited in claim 2, wherein the step of pre-treating the double-sided ITO glass further comprises following steps of:
(a) degreasing, comprising:
processing the double-sided ITO glass with a dip treatment in a standard acid bath at 15-28° C. for 5 minutes and thereafter washing with water for 2 minutes;
(b) etching, comprising:
processing the double-sided ITO glass with a dip treatment in an etching solution containing 10-50 g/L or 10-50 mL/L acidic etchant at 10-50° C. for 5 minutes and thereafter washing with water for 2 minutes to roughen the ITO surfaces and improve adhesion of plated layers;
(c) sensitizing, comprising:
processing the double-sided ITO glass with a dip treatment in a solution containing 10-50 mL/L palladium chloride and 15 mL/L KOH solution which contains KOH 0.1 mol/L at 10-50° C. for 1-10 minutes and thereafter washing with water for 2 minutes; and
(d) activating, comprising:
processing the double-sided ITO glass with a dip treatment in a solution containing 10 mL/L activator at 10-50° C. for 1-10 minutes and thereafter washing with water for 2 minutes.

6. The method, as recited in claim 2, wherein, under a situation of plating metal on a substrate having delicately arranged wirings, the chemical nickel plating art and the chemical gold plating art comprise following steps of:
providing the double-sided ITO glass in a sodium-free plating bath having lead as a metal stabilizer, a pH of 1-5, a temperature of 50-100° C. and a film stress of ±0 for chemically plating nickel thereon and then washing the double-sided ITO glass chemically plated with nickel with water for 2 minutes; and
thereafter providing the washed double-sided ITO glass in a cyanide plating bath having a pH of 1-5 and a temperature of 50-100° C. for chemically plating gold thereon.

7. The method, as recited in claim 2, wherein, under a situation of plating metal to thicken over 1 μm, the chemical nickel plating art and the chemical gold plating art comprise following steps of:
providing the double-sided ITO glass in a plating bath which has lead as a metal stabilizer, a pH of 1-5, a temperature of 50-100° C. and a low film stress and is suitable for trials and thickening the plating films, so as to chemically plate nickel thereon and then washing the double-sided ITO glass chemically plated with nickel with water for 2 minutes; and
thereafter providing the washed double-sided ITO glass in a lowly erosive plating bath having a pH of 6-10 and a temperature of 50-100° C. for chemically plating gold thereon.

8. The method, as recited in claim 2, wherein under a situation of satisfying RoHS, the chemical nickel plating art and the chemical gold plating art comprise steps of:
providing the double-sided ITO glass in a plating bath which has none metal stabilizer, a pH of 6-10, a temperature of 50-100° C. and a low film stress and is suitable for trials to chemically plate gold thereon, wherein sulfur-based additive is added to maintain stability of the plating bath, and washing the double-sided ITO glass chemically plated with nickel with water for 2 minutes; and
thereafter providing the washed double-sided ITO glass in a basically non-cyanide plating bath having a pH of 6-10 and a temperature of 50-100° C. for chemically plating gold thereon.
